(19) United States
(12) Patent Application Publication
(10) Pub. No.: US 2011/0020211 A1
(43) Pub. Date: Jan. 27, 2011

(54) High Throughput Carbon Nanotube Growth System, and Carbon Nanotubes and Carbon Nanofibers Formed Thereby

(75) Inventor: Ahalapitiya H. Jayatissa, Sylvania, OH (US)

Correspondence Address: MACMILLAN SOBANSKI & TODD, LLC, ONE MARITIME PLAZA FIFTH FLOOR, 720 WATER STREET, TOLEDO, OH, 43604-1619, US

(73) Assignee: UNIVERSITY OF TOLEDO, Toledo, OH (US)

(21) Appl. No.: 12/921,257

(22) PCT Filed: Mar. 9, 2009
(86) PCT No.: PCT/US2009/036533

§ 371 Date: Sep. 17, 2010

Related U.S. Application Data
(60) Provisional application No. 61/068,527, filed on Mar. 7, 2008.

(51) Int. Cl. D01F 9/12; C23C 16/00; C23C 16/455; B82B 3/00

(52) U.S. Cl. 423/447.2; 118/724; 427/249.1; 977/742; 977/750; 977/752; 977/843; 977/842

(57) ABSTRACT

A system is provided for forming carbon nanotubes comprising growing carbon nanotubes using a hot filament CVD system.

### CROSS-REFERENCE TO RELATED APPLICATIONS

The present invention claims the benefit of the provisional patent application Ser. No. 61/068,527 filed Mar. 7, 2008.

### STATEMENT REGARDING SPONSORED RESEARCH

This invention was made with government support under grants from URAF. The government has certain rights in this invention.

### TECHNICAL FIELD

There is disclosed herein a system for forming carbon nanotubes by growing carbon nanotubes using a hot filament chemical vapor deposition (CVD) system at pressure ranges from atmospheric to one thousand of atmospheric pressure.

### BACKGROUND OF THE INVENTION

There is no admission that the background art disclosed in this section legally constitutes prior art.

Carbon nanotubes are attracting great attention and interests because of their unique superior mechanical strength, varying electronic properties, high aspect ration, and large surface area. Those properties make carbon nanotubes an ideal material for such diverse uses as, for example, field emission display, adsorption of hydrogen, charge-based sensors, catalyst support, lithium batteries, biological catalyst, and nanoelectronic devices. As such, many methods have been developed to synthesis carbon nanotubes, such as arc deposition, chemical vapor deposition (CVD), and laser ablation and plasma deposition. However, the growth of carbon nanotubes is still one of the bottlenecks for carbon nanotechnology.

There is, therefore, a need to provide a synthesis system that does not involve methods that use complex extra energy such as plasma or laser, which are named as plasma-enhanced chemical vapor deposition (PECVD) and laser-enhanced chemical vapor deposition (LECVD). Also, such systems require synthesizing temperatures that are not low enough for many applications. For example one of the lowest temperatures to grow carbon nanotubes was reported as 400° C. which used a modified plasma-enhanced chemical vapor deposition system; however, this system has the following disadvantages: 1) needs a high vacuum in order to form the carbon nanotubes, 2) causes plasma damage to the other components of the electronic device; and, 3) causes the formation and deposition of thin film structures in other areas of the device.

There is a need for improved carbon nanotube growth methods and processes in order to meet the increasing requirements for high quality and quantity of carbon nanotubes.

There is a special need for such growth methods in order to meet certain applications and devices, such as biological sensor and field emission displays, that cannot be subjected to high temperatures.

There is also a need for a synthesis system that can be optimized to grow carbon nanotubes at low temperatures.

There is also a need for a synthesis system that can be optimized to grow carbon nanotubes at atmospheric pressure.

There is also a need for a synthesis system that can be used to grow carbon nanotubes in a roll-to-roll and/or batch processing.

Various objects and advantages of this invention will become apparent to those skilled in the art from the following detailed description of the preferred embodiment, when read in light of the accompanying drawings.

### BRIEF DESCRIPTION OF THE DRAWINGS

FIG. 1 is a schematic illustration of a chemical vapor deposition (CVD) system for forming carbon nanotubes.

FIG. 2 is a schematic illustration showing the temperatures and times sequences for forming carbon nanotubes on a substrate.

FIG. 3 is a schematic illustration showing steps in a process for forming carbon nanotubes on a substrate.

FIGS. 4A and 4B are SEM photographs of carbon nanotubes grown on a silicon substrate having a Co catalyst coating thereon at 400° C.; FIG. 4A taken at 10,000×; FIG. 4B taken at 80,000×.

FIG. 5A-5E are SEM photographs of carbon nanotubes where the carbon nanotubes were grown at: 500° C. (FIG. 5A); 600° C. (FIG. 5B); 700° C. (FIG. 5C); 800° C. (FIG. 5D); and 900° C. (FIG. 5E).

FIG. 6 is an SEM of carbon nanotubes grown on a glass substrate having a Co catalyst coating thereon at 500° C.

FIG. 7 is an SEM of carbon nanotubes grown on a silicon substrate having a Co and Ni catalyst thereon at 600° C.

FIGS. 8A-8C are high resolution transmission electronic microscopy (HT-TEM) photographs showing the nanostructure of carbon nanotubes grown on silicon substrate having a CO catalyst coating thereon at 500° C.; FIG. 8A shows a segment of carbon nanotubes; FIG. 8B shows two segments of carbon nanotubes having about 8-10 layers; and FIG. 8C shows catalyst feed on an end of carbon nanotubes.

FIG. 9 is a graph showing the Raman image of carbon nanotubes.

### SUMMARY OF THE INVENTION

In a first broad aspect, there is provided herein a method for forming carbon nanotubes, comprising the step of growing carbon nanotubes using a hot filament chemical vapor deposition (HWCVD) system.

In another broad aspect, there is provided herein a process for growing carbon nanotubes on a substrate in a furnace, comprising: injecting a carrier gas into a furnace having first and second heating zones for a first period of time; heating the first zone to a first temperature, and heating the second zone to a second temperature; heating a carbon radical formation mechanism in the first heating zone to a temperature between about 1500° C. to about 2000° C.; injecting carrier gas and a carbon feed source gas into at least the first heating zone; maintaining the first temperature and the second temperature for a set period of time sufficient for at least some of the carbon feed source gas to dissociate into carbon radical species; decreasing heat in the first and second heating zones at the end of the set period of time; ceasing injection of the feed gas while continuing injection of the carrier gas until the temperatures within the first and second heating zones reach desired lower temperatures.

In certain embodiments, the carbon radical species are deposited onto the substrate at a temperature ranging from about 400° C. to about 900° C.

The process can include varying one or more of: flow rate of the carbon feed source gas, temperature of the carbon radical species formation mechanism, and temperatures in the first and/or second heating zones.

In another broad aspect, there is provided herein carbon nanotubes formed using the system and process described herein.

These and other objects, features and advantages of the invention will become apparent to those skilled in the art from a reading of the detailed description and claims set forth below together with the drawings as described below.

### DETAILED DESCRIPTION OF THE PREFERRED EMBODIMENT(S)

In a broad aspect, there is provided, a hot filament assisted atmospheric chemical vapor deposition (HF-CVD) method for growing carbon nanotubes at very low temperatures. This system is simpler and the operation is easier compared with plasma enhanced CVD (PECVD) and laser-enhanced CVD (LECVD) methods.

In certain embodiments, the method includes growing carbon nanotubes by depositing carbon onto a substrate at a temperature ranging from about 400° C. to about 900° C.

In certain embodiments, the carbon comprises carbon radical species that have been decomposed from at least one carbon feed source. In certain embodiments, the carbon feed source comprises one or more of methane, branched or unbranched hydrocarbon materials, and cyclic hydrocarbons, and blends thereof, wherein carbon molecules disassociate within a temperature range of about 400° C. to about 900° C.

In certain embodiments, the method further includes coating at least one catalyst on a substrate prior to depositing the carbon onto the substrate. In certain embodiments, the substrate comprises one or more of a silicon or glass substrate.

In certain embodiments, the catalyst comprises one or more of copper, cobalt, nickel and iron, and/or alloys thereof. Further, in certain embodiments, the chirality of the carbon nanotubes can be altered by selection of one or more catalysts.

In certain embodiments, the catalyst is deposited on the substrate by a physical vapor deposition (PVD) process.

In another broad aspect, there is provided herein a hot filament chemical vapor deposition system for forming carbon nanotubes, comprising: a furnace having at least first heating zone and a second heating zone; each of the first and second heating zones being capable of being heated to different temperatures; an inlet in the furnace for receiving a supply of a carbon source feed; and, at least one mechanism capable of at least partially decomposing the carbon feed source into carbon radical species.

In certain embodiments, the carbon decomposing mechanism comprises a heat source at least partially within the first heating zone for decomposing the feed carbon source. In certain embodiments, the heat source comprises a heated filament comprised of a tungsten wire heated to a temperature in the range of about 1500° C. to about 2000° C.

In certain embodiments, the system includes at least one heating element for maintaining the temperature in the first heating zone for at least a period of time at a first temperature, and for maintaining the temperature in the second heating zone, wherein the temperature in the second zone is held for at least the same period of time at a second, and lower, temperature. In certain embodiments, the first temperature is about 500° C. and the second temperature is about 400° C.

In certain embodiments, the system can be operated at pressures ranging from atmospheric to about 10×10⁻³ of atmospheric pressure.

In certain embodiments, the system that be used to grow carbon in a substantially continuous (e.g., roll-to-roll) process. In such embodiments, the pressures can be generally be at atmospheric pressures such that supplies of substrate can be moved into and our of the furnace as the carbon nanotubes are formed.

In other certain embodiments, the system that be used to grow carbon in a batch process. In one such embodiment, the pressure can be at a partial vacuum pressure where the furnace is substantially sealed during the carbon forming process.

The system can be used for form single-walled carbon nanotubes and multi-walled carbon nanotubes simultaneously.

Also, the system can be used to form carbon nanotubes and nanofibers simultaneously. In one embodiment, the carbon nanofibers (non-hollow fibers) are formed by operating the process at temperatures in about the 400° C. to about 500° C. range, and in certain embodiments from about 450° C. to about 500° C.

In certain embodiments, the carbon nanotubes formed have a specific physical structure. In one embodiment, the carbon nanotubes have a helixed structure. In one non-limiting example, use of copper alloys can be used to form carbon nanotubes having a helixed structure. In one embodiment, a useful copper alloy is a copper-iron alloy. In other embodiments, the copper alloys can include one or more of cobalt, iron and/or nickel.

The following examples are intended to illustrate preferred embodiments of the invention and should not be interpreted to limit the scope of the invention as defined in the claims, unless so specified.

### EXAMPLES

### Hot Filament CVD Nanotube Growth System

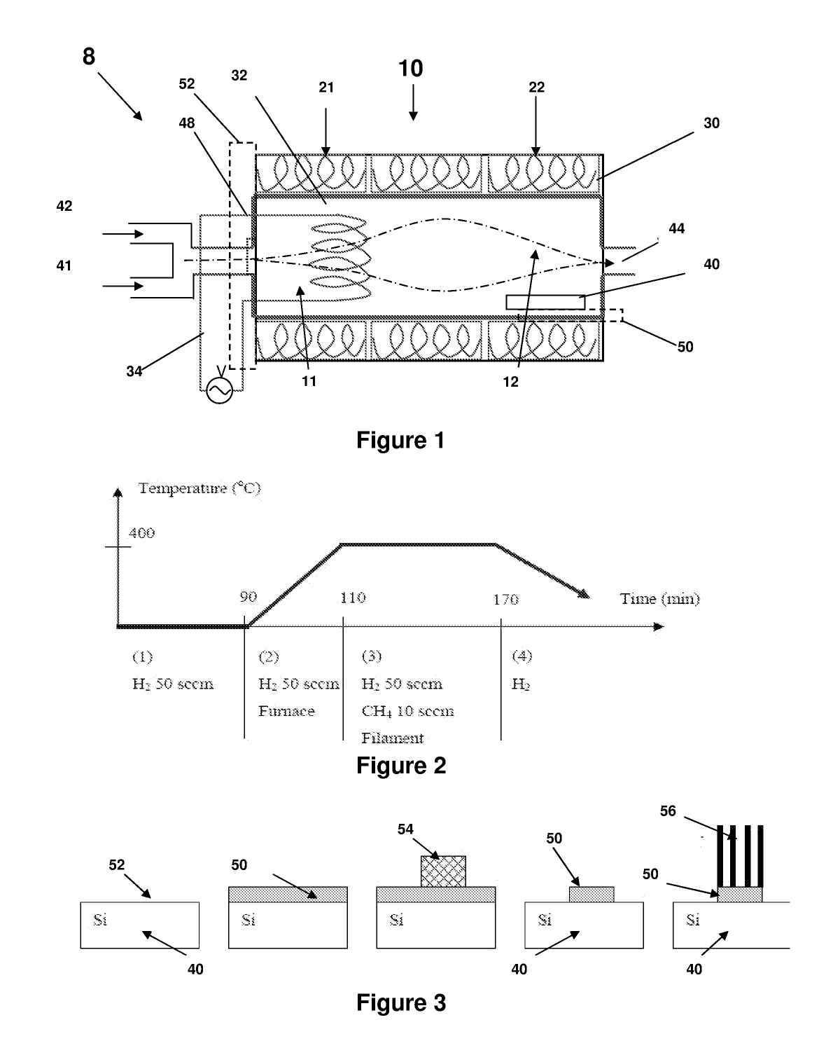

Referring now to FIG. 1, schematic illustration of a hot filament CVD carbon nanotubes formation system 8 is shown. The system includes a furnace 10 having a quartz tube 30 positioned therein. The quartz tube 30 has multiple heating zones, here shown as first and second heating zones 11 and 12, respectively. In one embodiment, the system 10 can be a hot filament CVD (for example, a Lindberg/Blue 3-Zone Tube) furnace 10. The first and second heating zones 11 and 12 can be heated externally by one or more heating elements 21 and 22, respectively. The heating elements 21 and 22 can be separately programmed to heat each of the first and second heating zones 11 and 12, for specific times and at specifics temperatures. In one embodiment, a UP150 Program Temperature Controller can be used.

The furnace 10 includes a gas inlet 41 for receiving a supply 42 of carrier gas and, at time, a supply 41 of feed gas. The gas inlet 41 is positioned to allow the gases to enter the first heating zone 11. The gas inlet 41 can be sealed at times during the carbon nanotubes formation process by a seal 48.

The furnace 10 includes at least one gas outlet 44 at an opposing end of the quartz tube 30 through which the reaction gases are exhausted, as is further explained herein.

The carbon nanotubes formation system 8 further includes a carbon radical formation mechanism 32 that is positioned in the first heating zone 11. The carbon radical formation mechanism 32 can be a hot wire filament, and for ease of explanation herein, will be so called. The filament 32 is positioned in the first heating zone 11 in proximity to the gas inlet such that the filament 32 heats the feed gas and the carrier gas as they are being injected into the first heating zone 11. In certain embodiments, the filament 32 can comprise a tungsten wire of 0.5 mm in diameter and 30 cm in length that is shaped into a coil.

The filament 32 is connected to a power supply 34 which supplies energy (e.g., by applying about 10V voltage by an AC power regulator), to the filament 32. In certain embodiments, the filament 32 is heated to about 1500 to about 2000° C. When a tungsten filament is used, as the filament is heated, the color of filament 32 changes from red to white, indicating that the 2000° C. is being reached.

In operation, the carrier gas and feed gas are mixed and passed into the quartz tube 30. When the feed and carrier gases pass by the hot filament 32, the feed gas is decomposed into carbon radical species and hydrogen. The carrier gas then carries the carbon radical species to one or more substrates that are within the second zone 12. Individual carbon radical species are deposited on each other, collecting as carbon nanotubes on the substrate 40.

In certain embodiments, the system can be operated at pressures ranging from atmospheric to about 10×10⁻³ of atmospheric pressure.

In certain embodiments, the system that be used to grow carbon in a substantially continuous (e.g., roll-to-roll) process. In such embodiments, the pressures can be generally be at atmospheric pressures such that supplies of substrate can be moved into and our of the furnace as the carbon nanotubes are formed.

In other certain embodiments, the system that be used to grow carbon in a batch process. In one such embodiment, the pressure can be at a partial vacuum pressure where the furnace is at least partially sealed during the carbon forming process. FIG. 1 includes a schematic illustration of an assembly 50 for providing a substantially continuous supply of substrate upon which carbon nanotubes are formed. Also, in certain embodiments, the system can include one or more mechanisms 53 for varying one or more of: flow rate of the carbon feed source gas, temperature of the carbon radical species formation mechanism, and temperatures in the first and/or second heating zones.

### Growth of Carbon Nanotubes

FIG. 2 is a schematic illustration of the process for growing carbon nanotubes on a substrate 40. In one embodiment, the temperature/time sequence for growing carbon nanotubes includes:

a 1^{st} step of:
(1a) placing a substrate in a second heating zone in a furnace; and
(1b) injecting a carrier gas into the first and second heating zones for a purging cycle;

a 2^{nd} step of:
(2a) injecting additional carrier gas into the first and second heating zones;
(2b) pre-heating the first zone to a first temperature; and
(2c) pre-heating the second zone to a second temperature that is lower than the first temperature of the first heating zone;

a 3^{rd} step of:
(3a) applying power to cause the carbon radical formation mechanism (i.e., filament) to reach a desired temperature;
(3b) injecting a mixture of feed gas and additional carrier gas into the first heating zone in an area adjacent to the carbon radical formation mechanism; and
(3c) maintaining the first temperature in the first and second zones for a set period of time, and maintaining the second temperature in the second heating zone for same set period of time;

and, a 4^{th} step of:
(4a) turning off power (and, thus heat from) to the carbon radical formation mechanism,
(4b) reducing heat in the first and second heating zones;
(4c) ceasing injection of the feed gas; and
(4d) continuing injection of the carrier gas until the temperatures within the first and second heating zones reach a third, and lower, temperature.

In certain embodiments, the substrate 40 can include have a suitable catalyst 50 coated on at least a top surface 52 of the substrate 40. In certain embodiments, the catalyst 50 can be deposited in a desired pattern on the top surface 52 of the substrate 50.

In the embodiment shown in FIG. 3, the process to grow carbon nanotubes includes: (a) providing a substrate 40, (b) coating the substrate 40 with a catalyst 52 (for example, using a physical vapor deposition (PVD) process), (c), forming a suitable pattern on the catalyst 52 (for example, by etching using photolithography), and (d) growing carbon nanotubes 56 on the catalyst 52 using the carbon nanotube formation process described herein.

In certain non-limiting embodiments, the substrate can include silicon wafer and glass substrates, optionally coated with a suitable metallic catalyst, such as cobalt (Co), nickel (Ni) or iron (Fe). The metallic catalyst can be coated on the substrate by a suitable physical vapor deposition (PVD) process or other coating processes. In certain embodiments, the thickness of the catalyst 52 coated on substrate can range from about 0.5 nm to about 50 nm.

In one embodiment, the heating progress was set by programming the UP150 Program Temperature Controller such that the temperatures in the first heating zone 11 was were set at about 500° C., and the temperature in the second heating zone 12 was set at about 400° C.

One example of a temperature/time profile for a nanotube growth sequence useful to grow carbon nanotubes is shown in FIG. 2. In one embodiment, the temperature/time sequence for growing carbon nanotubes includes:

(1) injecting a carrier gas (e.g., H₂ @˜50 sccm for 90 minutes) in a quartz tube 30 having first and second heating zones;

(2a) injecting additional carrier gas (e.g., H₂ @˜50 sccm) into the quartz tube 30,

(2b) pre-heating the first heating second zone to a first temperature (e.g., ˜500° C.),

(2c) pre-heating the second zone 12 to a second temperature (e.g., ˜400° C.) that is lower than the first temperature of the first heating second zone;

(3a) applying power to the filament 32 (e.g., ˜10V to ˜15V voltage to a tungsten filament until the filament turns from red and approached white color and/or the filament temperature is ˜1500° C. to ˜2000° C.);

(3b) injecting feed gas (e.g., CH₄ @˜10 sccm) and additional carrier gas (e.g., H₂ @˜50 sccm) and into at least the first heating zone 11 in the quartz tube 30, and

(3c) maintaining the first temperature in the first heating zone for a first set period of time, and maintaining the second temperature in the second heating zone for the same set period of time (e.g., ˜0.5 to ˜1.5 hours);

(4a) turning off power (and, thus heat from) to the filament 32,

(4b) ceasing to supply heat to the first and second heating zones 11 and 12;

(4c) ceasing injection of the feed gas (e.g., CH₄); and

(4d) continuing injection of the carrier gas (e.g., H₂) into the furnace 10, until the temperatures within the first and second heating zones 11 and 12 reach a third temperature (e.g., cooled down, and, in some embodiments, cooling to about to room temperature).

In order to compare the growth of carbon nanotubes 56 at lower temperatures to the growth of nanotubes at higher temperatures, the experiment was repeated at the same condition by changing only the temperature of reaction area within the second heating zone 12 to 500° C., 600° C., 700° C., 800° C. and 900° C.

### Characterization of Carbon Nanotubes

After carbon nanotubes growth, the CVD system was cooled down to room temperature. The samples coated with carbon nanotubes were characterized by scanning electron microscopy (Philips XL30 FEG SEM), high-resolution transmission electronic microscopy (JEOL 3011 High Resolution Electron Microscope), and Raman spectroscopy. SEM was used to analyze the samples morphology, and HR-TEM was used to inspect carbon nanotubes nanostructure. Raman was used to determine the carbon nanotubes.

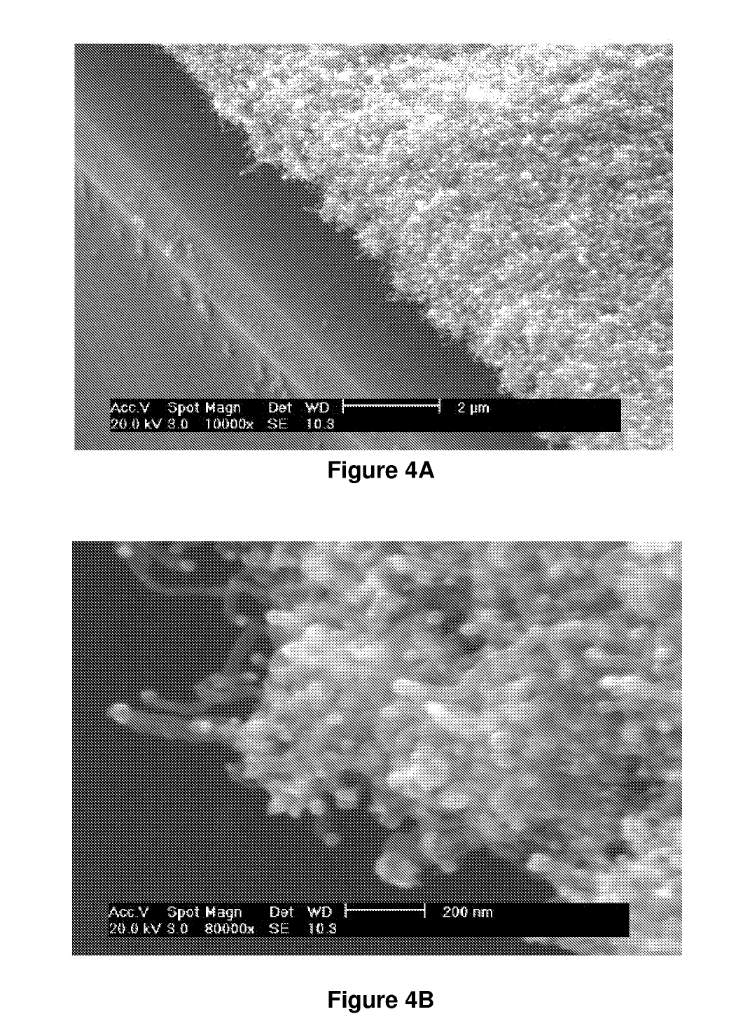

Carbon nanotubes were found on the samples grown with Co, Fe and Ni at low temperature and at high temperature. In certain embodiments, carbon nanotubes were grown at temperatures as low as about 400° C., which is the lowest temperature recorded to grow carbon nanotubes. In the SEMs of carbon nanotubes grown at the lowest temperature 400° C. (shown in FIG. 4A and FIG. 4B), the carbon nanotubes were grown with a Co catalyst on a silicon substrate. In the embodiment shown in FIG. 4B, the diameter of carbon nanotubes is about 20 nm.

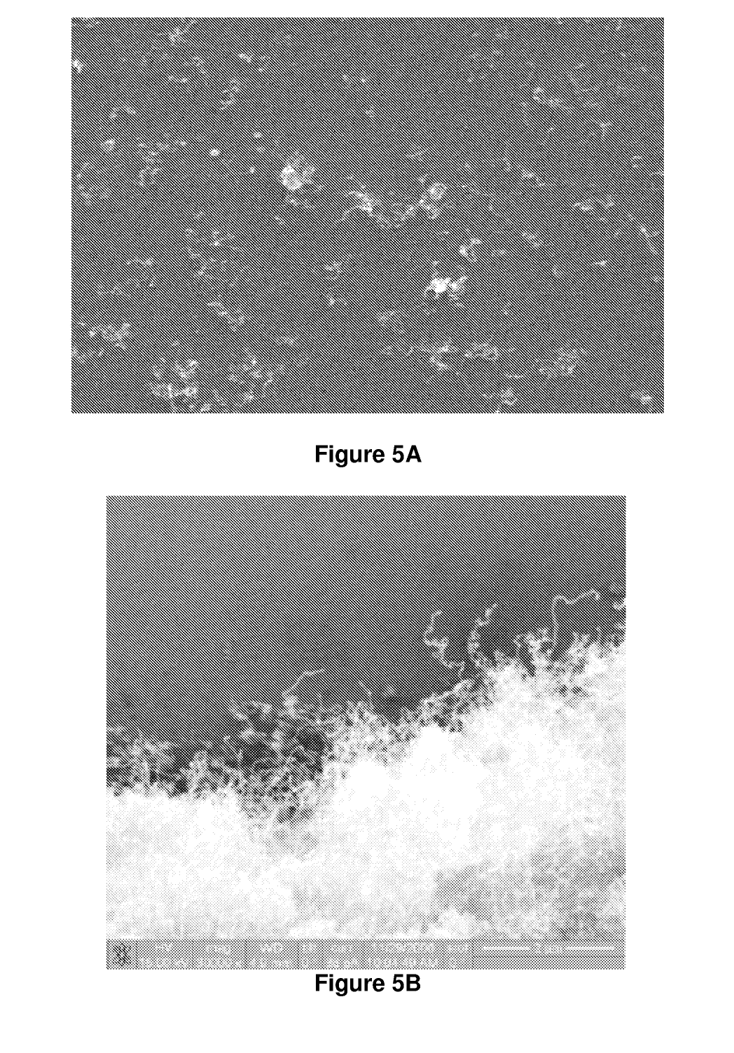

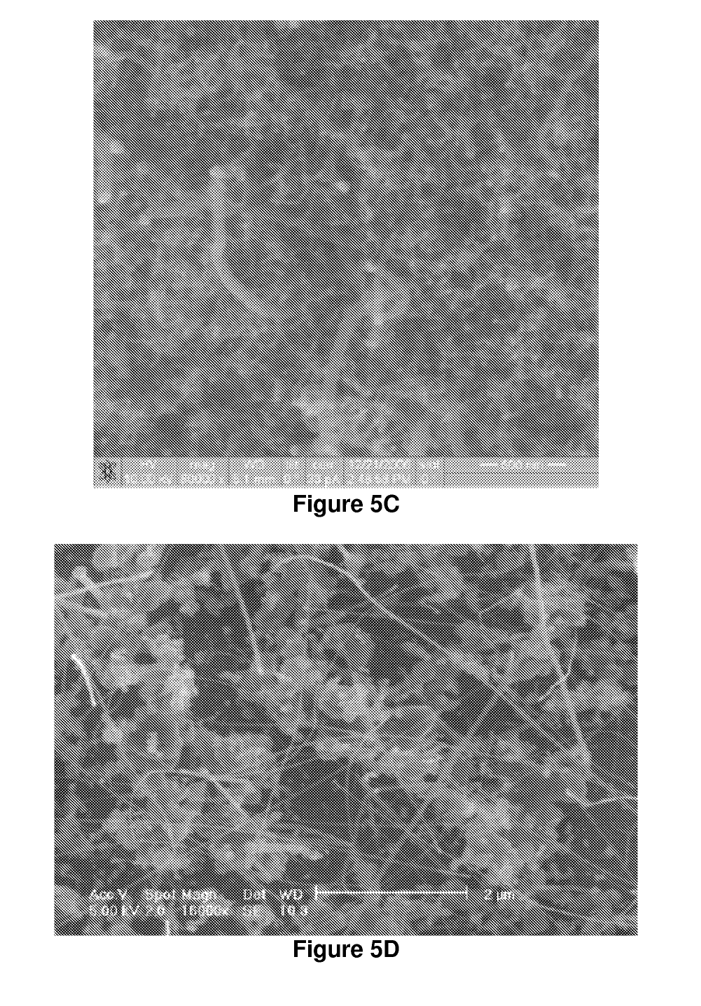

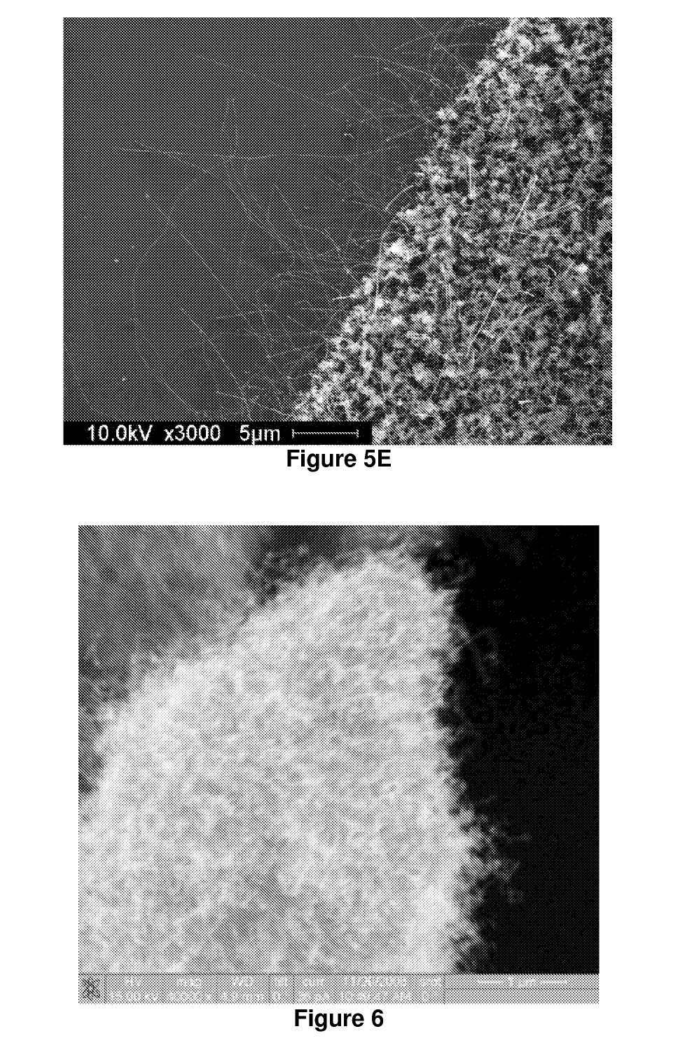

Carbon nanotubes were also grown at 500° C., 600° C., 700° C., 800° C. and 900° C., as shown as FIGS. 5A-5E. As the temperatures changed from 500° C. to 900° C., the carbon nanotubes grew faster and longer; however more amorphous carbon was deposited also. In the example shown in FIG. 5A, there were few carbon nanotubes grown on the substrate at 500° C. since very thin Co catalyst was coated on the silicon substrate.

In the example shown in FIG. 5B, the carbon nanotubes are grown at the edge of Co catalyst pattern on the silicon substrate. When the temperature was raised to 700° C., the catalyst melted and merged to form bigger particles. Small and larger carbon nanotubes were grown substantially, as shown in FIG. 5C. After the temperature approached 800° C. and 900° C., the carbon nanotubes grew faster and longer, but more amorphous carbon was also deposited shown as FIG. 5D and FIG. 5E.

While in the past, it had been difficult to grow carbon nanotubes on glass using traditional methods since the glass substrate melted at temperatures higher than 500° C. 600° C., now using the hot filament CVD carbon nanotube growth system described herein, it is possible to grow carbon nanotubes on glass substrates. In the hot filament CVD carbon nanotube growth system described herein, the carbon nanotubes can be grown at temperature at, and above, about 500° C. FIG. 6 is an SEM photograph of carbon nanotubes grown with Co on a glass substrate at 500° C.

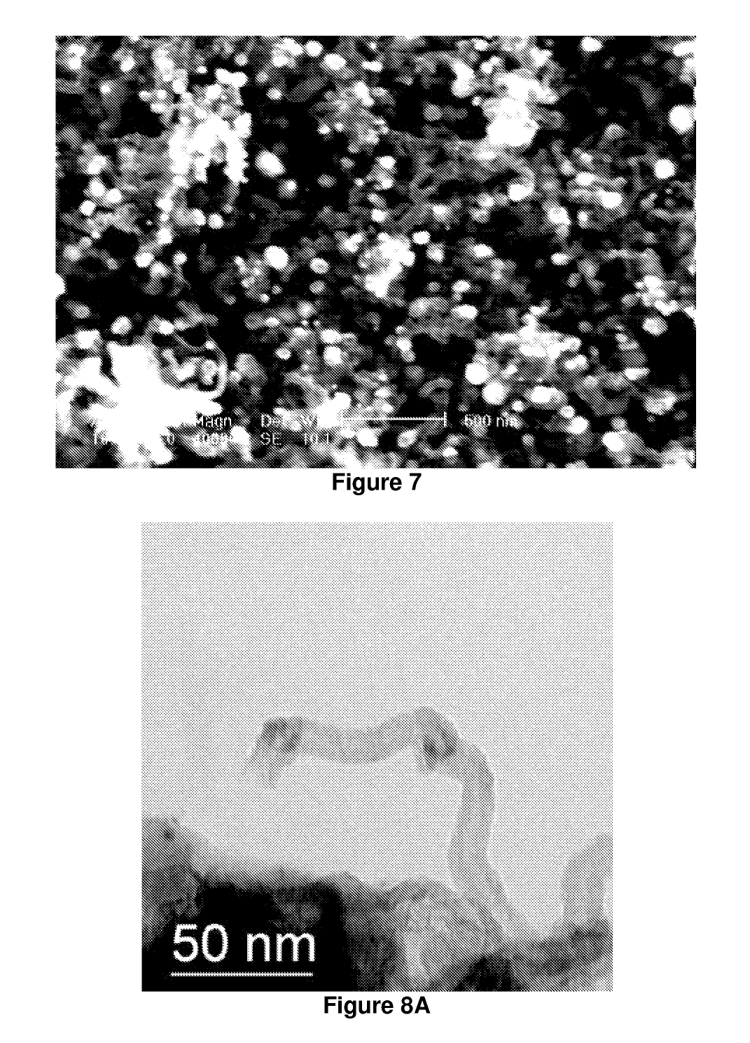

In other embodiments, other suitable catalysts such as Fe and Ni are also useful for growing carbon nanotubes. In the embodiment shown in FIG. 7, an alloy of Co and Ni was used as catalysts to grow carbon nanotubes on a silicon substrate at 600° C.

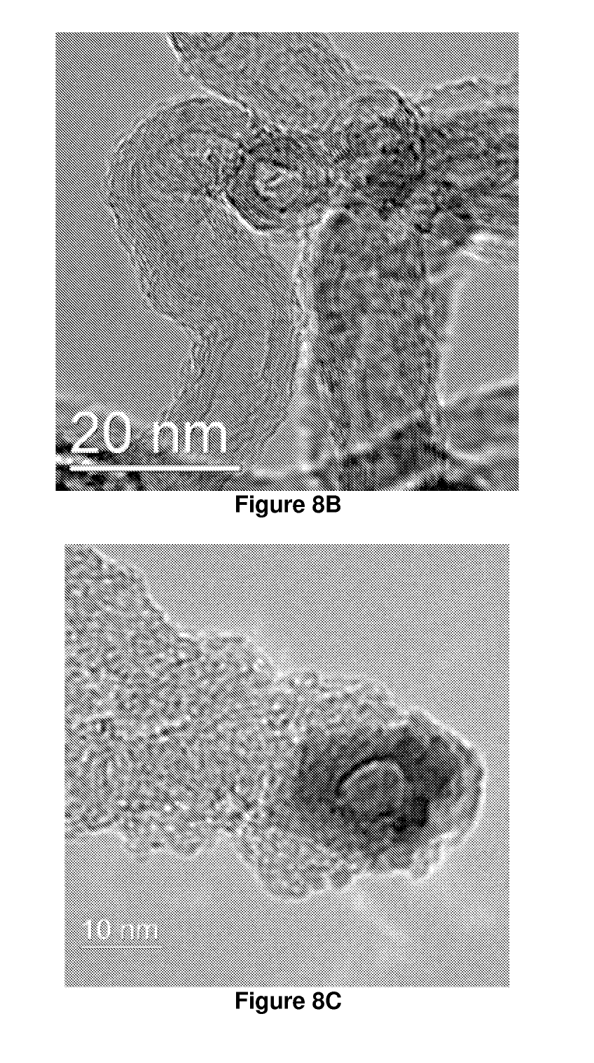

The high-resolution transmission electronic microscopy (HR-TEM) was used to inspect the nanostructure of carbon nanotubes grown with Co on silicon substrate at 500° C. FIG. 8A shows a segment of carbon nanotubes. From FIG. 8B, it can be found that there are about 8 to about 10 layers in the two segments of carbon nanotubes. FIG. 8C shows a catalyst feed was found at a top of carbon nanotubes. The size of catalyst feed is about 10 nm, which is smaller than the 15 nm diameter of carbon nanotubes.

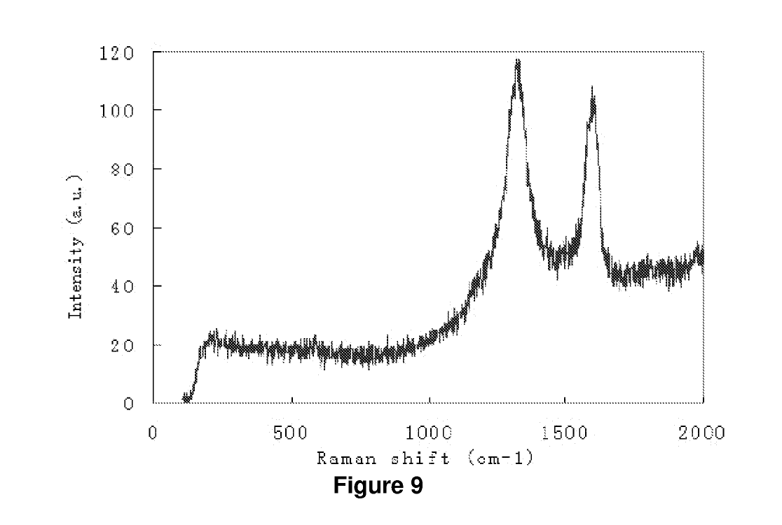

The carbon nanotubes were also characterized by Raman spectroscopy. As seen in FIG. 9, two peaks were observed at about 1330 cm-1 and 1600 cm-1. The first peak corresponds to the disorder of the graphite structure (D-band). The other peak is related to the high-frequency E₂g first-order mode of carbon nanotubes (G-band). It is to be understood that those two peaks can be used to determine the presence of carbon nanotubes.

Further, in addition to temperature, other parameters can influence the growth of carbon nanotubes, such as catalyst, gas flow rate, voltage applied on filament, and substrates treatment, and that the use of such parameters to aid in the growth of carbon nanotubes is within certain contemplated embodiments of the present invention, as described herein.

While the invention has been described with reference to various and preferred embodiments, it should be understood by those skilled in the art that various changes may be made and equivalents may be substituted for elements thereof without departing from the essential scope of the invention. In addition, many modifications may be made to adapt a particular situation or material to the teachings of the invention without departing from the essential scope thereof. Therefore, it is intended that the invention not be limited to the particular embodiment disclosed herein contemplated for carrying out this invention, but that the invention will include all embodiments falling within the scope of the claims.

### REFERENCES

The publication and other material used herein to illuminate the invention or provide additional details respecting the practice of the invention, are incorporated by reference herein, and for convenience are provided in the following bibliography.

Citation of any of the documents recited herein is not intended as an admission that any of the foregoing is pertinent prior art. All statements as to the date or representation as to the contents of these documents is based on the information available to the applicant and does not constitute any admission as to the correctness of the dates or contents of these documents.

S. Iijima, “Helical Microtubules of Graphitic Carbon”, Nature 354 (1991) 56-58.

S. Musso, G. Fanchini, A. Tagliaferro, “Growth of vertically aligned carbon nanotubes by CVD by evaporation of carbon precursors”, Diamond & Related Materials 14 (2005) 784-789.

Maoshuiai He, Shuang Zhou, Jin Zhang, Zhongfan Liu, Colin Robinson, “CVD Growth of N-Doped Carbon Nanotubes on Silicon Substrates and Its Mechanism”, J. Phys. Chem. B 109 (2005) 9275-9279.

Y. J. Li, Z. Sun, S. P. Lau, G. Y. Chen, B. K. Tay, “Carbon nanotube films prepared by thermal chemical vapor deposition at low temperature for field emission applications”, Applied Physics Letters Vol. 79, No. 11, September (2001) 1670-1672.

C. Liu, Y. Y. Fan, M. Liu, H. T. Cong, H. M. Cheng, M. S. Dresselhaus, Hydrogen Storage in Single-Walled Carbon Nanotubes at Room Temperature, Science Vol. 286. No. 5442, November (1999) 1127-1129.

Jing Guo, Edwin C. Kan, Udayan Ganguly, Yuegang Zhang, “High sensitivity and nonlinearity of carbon nanotube charge-based sensors”, Journal of Applied Physics 99, 084301 (2006).

Chi-Yuan Lu, Ming-Yen Wey, “The performance of CNT as catalyst support on CO oxidation at low temperature”, Fuel 86 (2007) 1153-1161.

Ki-Hong Lee, Jeoong-Min Cho, Wolfgang Sigmund, “Control of growth orientation for carbon nanotubes”, Applied Physics Letters, Vol. 82, No. 3, January (2003).

S. Porro, S. Musso, M. Giorcelli, A. Chiodoni, A. Tagliaferro, “Optimization of a thermal-CVD system for carbon nanotube growth”, Physica E 37 (2007) 16-20.

M. Dubosc, T. Minea, M. P. Besland, C. Cardinaud, A. Granier, A. Gohier, S. Point, J. Torres, “Low temperature plasma carbon nanotubes growth on patterned catalyst”, Microelectronic Engineering 83 (2006) 2427-2431.

S. Hofmann, C. Ducati, J. Robertson, B. Kleinsorge, “Low-temperature growth of carbon nanotubes by plasma-enhanced chemical vapor deposition”, Applied Physics Letters Vol. 83, No. 1, July (2003).

Tetsuya Shiroishi, Takao Sawada, Akihiko Hosono, Shuhei Nakata, Yasunori Kanazawa, Mikio Takai, “Low-temperature growth of carbon nanotube by thermal chemical vapor deposition with FeZrN catalyst”, J. Vac. Sci. Technol. B, Vol. 22, No. 4, July/August (2004) 1834-1837.

H. J. Yoona, H. S. Kanga, J. S. Shina, J. S. Kima, K. J. Sona, C. H. Leea, C. O. Kima, J. P. Honga, S. N. Chab, B. G. Songb, J. M. Kimb, N. S. Lee, “External-grid induced well-aligned carbon nanotubes grown on corning glass at extremely low temperature of about 400° C.”, Physica B 323 (2002) 344-346.

M. S. Dresselhaus, G. Dresselhaus, A. Jorio, A. G. Souza Filho, R. Saito, “Raman spectroscopy on isolated single wall carbon nanotubes”, Carbon 40 (2002) 2043-2061.

1-21. (canceled)

22. A hot filament chemical vapor deposition system for forming carbon nanotubes, comprising:
a furnace having at least a first heating zone and a second heating zone; each of the first and second heating zones being capable of being heated to different temperatures;
an inlet in the furnace for receiving a supply of a carbon source feed; and,
at least one mechanism capable of at least partially decomposing the carbon feed source into carbon radical species.

23. The system of the claim 22, wherein the carbon decomposing mechanism comprises a heat source at least partially within the first heating zone for decomposing the feed carbon source.

24. The system of claim 22, wherein the heat source comprises a heated filament comprised of a tungsten wire heated to a temperature in the range of about 1500° C. to about 2000° C.

25. The system of claim 22, including at least one heating element for maintaining the temperature in the first heating zone for at least a period of time at a first temperature, and for maintaining the temperature in the second heating zone, wherein the temperature in the second zone is held for at least the same period of time at a second, and lower, temperature.

26. The system of claim 22, wherein the first temperature is about 500° C. and the second temperature is about 400° C.

27. The system of claim 22, further including an assembly for providing a substantially continuous supply of substrate upon which carbon nanotubes are formed.

28. The system of claim 22, further including one or more mechanism for varying one or more of: flow rate of the carbon feed source gas, temperature of the carbon radical species formation mechanism, and temperatures in the first and/or second heating zones.

29. A process for growing carbon nanotubes on a substrate in a furnace, comprising:
injecting a carrier gas into a furnace having first and second heating zones for a first period of time;
heating the first zone to a first temperature, and heating the second zone to a second temperature;
heating a carbon radical formation mechanism in the first heating zone to a temperature between about 1500° C. to about 2000° C.;
injecting carrier gas and a carbon feed source gas into at least the first heating zone;
maintaining the first temperature and the second temperature for a set period of time sufficient for at least some of the carbon feed source gas to dissociate into carbon radical species;
decreasing heat in the first and second heating zones at the end of the set period of time;
ceasing injection of the feed gas while continuing injection of the carrier gas until the temperatures within the first and second heating zones reach desired lower temperatures.

30. The process of claim 29, including growing carbon nanotubes by depositing carbon onto a substrate at a temperature ranging from about 400° C. to about 900° C.

31. The process of claim 29, including growing carbon nanotubes by depositing carbon onto a substrate at atmospheric pressure.

32. The process of claim 29, including growing carbon nanotubes by depositing carbon onto a substrate at pressures ranging from about atmospheric to about 10×10⁻³ of atmospheric pressure.

33. The process of claim 29, including growing carbon nanotubes by depositing carbon onto a substrate in a substantially continuous operation.

34. The process of claim 29, including growing carbon nanotubes by depositing carbon onto a substrate in a batch operation.

35. The process of claim 29, wherein the carbon comprises carbon radical species that decompose from at least one carbon feed source.

36. The process of claim 35, wherein the carbon feed source comprises one or more of methane, branched or unbranched hydrocarbon materials, and cyclic hydrocarbons, and blends thereof, wherein carbon molecules disassociate within a temperature range of about 400° C. to about 900° C.

37. The process of claim 29, wherein single-walled carbon nanotubes and multi-walled carbon nanotubes are formed simultaneously.

38. The process of claim 29, wherein carbon nanotubes and nanofibers are formed simultaneously.

39. The process of claim 38, wherein the carbon nanofibers are formed at temperatures in the range about the 400° C. to about 500° C.

40. The process of claim 38, wherein the carbon nanofibers are formed at temperatures in about the 450° C. to about 500° C. range.

41. The process of claim 29, further including coating at least one catalyst on a substrate, and depositing the carbon onto the substrate.

42. The process of claim 41, wherein the substrate comprises one or more of a silicon or glass substrate.

43. The process of claim 41, wherein the catalyst comprises one or more of copper, cobalt, nickel and iron, and alloys thereof.

44. The process of claim 41, wherein chirality of the carbon nanotubes is altered by selection of one or more catalysts.

45. The process of claim 29, wherein the carbon nanotubes formed have a specific physical structure.

46. The process of claim 45, wherein the carbon nanotubes have a helixed structure.

47. The process of claim 46, wherein the carbon nanotubes are formed on a substrate having a copper-based catalyst at least partially coated thereon.

48. The process of claim 47, wherein the catalyst comprises a copper-iron alloy.

49. The process of claim 41, wherein the catalyst is deposited on the substrate by a physical vapor deposition (PVD) process.

50. The process of claim 29, further including varying one or more of:
flow rate of the carbon feed source gas, temperature of the carbon radical species formation mechanism, and temperatures in the first and/or second heating zones.

51. Carbon nanotubes formed by the method of claim 1.

52. Carbon nanotubes formed using the system of claim 22.

53. Carbon nanotubes formed by the process of claim 29.
